(19) United States
(12) Patent Application Publication
(10) Pub. No.: US 2025/0067777 A1
(43) Pub. Date: Feb. 27, 2025

(54) BUS MEASUREMENTS TO CALCULATE AND DISPLAY TIMING CHARACTERISTICS OF BUS PROTOCOLS IN TEST AND MEASUREMENT INSTRUMENTS

(71) Applicant: Tektronix, Inc., Beaverton, OR (US)

(72) Inventors: Niranjan R Hegde, Siddapur (IN); Archana I. Akkalkot, Bengaluru (IN); Sushree Sangita Dash, Bangalore South (IN)

(21) Appl. No.: 18/807,267

(22) Filed: Aug. 16, 2024

(30) Foreign Application Priority Data
Aug. 25, 2023 (IN) 202321057202

(51) Int. Cl. G01R 13/02

(52) U.S. Cl. CPC G01R 13/02

(57) ABSTRACT

Systems and methods implement measuring, in a test and measurement instrument, operational signal timing parameters of electrical signals being communicated over an electrical bus by a device under test. A bus timing characteristics analyzer identifies nominal signal timing parameters for the acquired electrical signals. The nominal signal timing parameters are defined by the bus protocol and defining timing criteria for the electrical signals. The analyzer measures operational signal timing parameters for each of the acquired electrical signals and compares, for each of the electrical signals, the operational signal timing parameters to the nominal signal timing parameters to determine whether the operational signal timing parameters satisfy the timing criteria. The analyzer then displays, on the test and measurement instrument, a visual indication for each of the electrical signals indicating whether the operational signal timing parameters for the electrical signal satisfy the timing criteria.

### CROSS-REFERENCE TO RELATED APPLICATIONS

This disclosure claims priority under 35 U.S.C. § 119 to Indian Provisional Patent Application No. 202321057202, titled “BUS MEASUREMENT TO CALCULATE AND DISPLAY THE REPORT FOR TIMING CHARACTERISTICS OF ANY BUS PROTOCOL IN OSCILLOSCOPE,” filed on Aug. 25, 2023, the disclosure of which is incorporated herein by reference in its entirety.

### TECHNICAL FIELD

The present disclosure relates generally to acquiring and decoding electrical signals being communicated over an electrical bus with a test and measurement instrument, and more specifically to a test and measurement instrument that determines whether the acquired electrical signals to be decoded satisfy required timing characteristics defined by a bus protocol of the electrical bus.

### BACKGROUND

In test and measurement instruments, such as oscilloscopes, protocol decode is the process of translating or decoding electrical signals being communicated over a serial electrical bus by a device under test (DUT). The protocol decode translates these electrical signals into corresponding bit sequences as defined by a bus protocol of the electrical bus. This functionality of test and measurement instruments enables designers to verify design and operation of the DUT using decoded messages or frames being communicated on the electrical bus. Many different types of serial buses are used today, each serial bus having an associated bus protocol defined by a corresponding standard. Each bus protocol includes a protocol layer specifying encoding techniques, definitions for different frames and packets, specific bit patterns, and error handling for the electrical signals being communicated over the electrical bus.

In protocol decode, a DUT being tested is coupled to an electrical bus and a test and measurement instrument acquires electrical signals being communicated over the electrical bus to and from the DUT. As part of this process, a user configures a protocol decoder in the instrument including selecting the type of electrical bus being tested as well as the configuration of thresholds and other related settings defined for the selected bus through a bus configuration menu of the protocol decoder. The protocol decoder in the instrument then translates or decodes the acquired electrical signals to generate corresponding frames formed by these electrical signals according to the bus protocol. The decoding includes identifying frame information such as start of a frame and end of frame as well as checking values of different packets being communicated as part of the frame according to the bus protocol for the electrical bus. The protocol decoder identifies errors in the decoded packets and displays the decoded packets along with an indication of detected errors for review by a user. The errors may include, for example, packets having improper values (i.e. sequences of bits) and error checking including cyclic redundancy check (CRC) or parity check for the decoded packets.

The configuration of the protocol decoder includes the setting of thresholds that are used during decoding of the electrical signals to decode “1” and “0” bits in the sequence of bits or bit stream being communicated over the electrical bus. The protocol decoder uses these thresholds, along with information from the bus protocol for the electrical bus over which the electrical signals are being communicated, to decode the signals. For example, the protocol decoder uses information about the format of frames defined for the bus protocol to detect the start and end of frames and to detect different types of frames like address frames and data frames.

Signal timing characteristics of the electrical signals being communicated over the electrical bus are also defined by the bus protocol. More specifically, the signal timing characteristics are defined by nominal signal timing parameters defined for the bus protocol. For example, the nominal signal timing parameters may include rise time and fall time parameters for rising and falling edges, respectively, of the electrical signals, setup and hold start condition time parameters, data setup and hold time parameters, a stop condition setup time parameter, a buffer time parameter defining a minimum time between a stop and start condition on the electrical bus, and so on, depending on the protocol of the specific electrical bus being utilized. The electrical signals being communicated over an electrical bus must satisfy or comply with the timing characteristics defined by the associated nominal signal timing parameters to ensure proper operation of the electrical bus. Failure of the electrical signals to comply with these nominal signal timing parameters may result in erroneous information being communicated over the electrical bus. Improved techniques are required for test and measurement instruments to ensure acquired electrical signals to be decoded by a protocol decoder satisfy required timing characteristics defined by the corresponding bus protocol as part of decoding the acquired electrical signals.

### BRIEF DESCRIPTION OF ACCOMPANYING DRAWINGS

FIG. 1 is a block diagram of a test and measurement system including a test and measurement instrument containing a bus timing characteristics analyzer for analyzing timing characteristics of electrical signals being communicated over an electrical bus in accordance with embodiments of the disclosure.

FIG. 2 is a signal timing diagram illustrating a number of nominal signal timing parameters associated with data and clock signals of an inter-integrated circuit (I2C) electrical bus.

FIG. 3 is a signal timing diagram illustrating the data and clock signals of an I2C bus and showing an address frame and a data frame communicated on the bus according to the I2C bus protocol.

FIG. 4 is a signal timing diagram showing data and clock signals acquired by the instrument and decoded data and address frames as generated by a protocol decoder of the test and measurement instrument.

FIG. 5 is a flowchart of a process executed by the bus timing characteristics analyzer of FIG. 1 for analyzing the timing characteristics of data and clock signals communicated over an I2C bus in accordance with embodiments of the disclosure.

FIG. 6 illustrates a sample configuration display rendered on a user interface by the bus timing characteristics analyzer of FIG. 1 for configuration by a user of the bus timing characteristics analyzer in accordance with embodiments of the disclosure.

FIG. 7 is a bus configuration display that is displayed by the bus timing characteristics analyzer of FIG. 1 on a user interface of the test and measurement instrument in accordance with embodiments of the disclosure.

FIG. 8 illustrates a bus timing results configuration display rendered by the bus timing characteristics analyzer on the user interface of the test and measurement instrument in accordance with embodiments of the disclosure.

FIG. 9 illustrates a bus timing results display presented by the bus timing characteristics analyzer on the user interface of the test and measurement instrument in accordance with embodiments of the disclosure.

FIG. 10 illustrates another example of a bus timing results display that further includes time domain representations of the acquired electrical in accordance with embodiments of the disclosure.

### DETAILED DESCRIPTION

Embodiments of the disclosure are directed to methods of analyzing timing characteristics of electrical signals being communicated by a device under test (DUT) over an electrical bus, and in a test and measurement instrument for testing the DUT and to systems for implementing these methods in accordance with embodiments of the disclosure.

According to embodiments of the disclosure, a bus timing characteristics analyzer of a test and measurement instrument determines whether the timing characteristics of electrical signals being communicated over an electrical bus satisfy required timing criteria or characteristics for these electrical signals as defined by a bus protocol of the electrical bus. The bus timing characteristics analyzer is configured, in response to user input, for a desired type of electrical bus that is being used, and in response to the user input, loads or retrieves nominal signal timing parameters for the electrical signals of the desired bus. The nominal signal timing parameters are defined by the bus protocol and define timing criteria for the electrical signals. The test and measurement instrument captures or acquires the electrical signals being communicated over the bus to and from the DUT and the bus timing characteristics analyzer measures operational signal timing parameters for the acquired electrical signals. The bus timing characteristics analyzer then compares the operational signal timing parameters to the nominal signal timing parameters to determine whether the operational signal timing parameters satisfy the defined timing criteria. A visual indication is then displayed on the test and measurement instrument by the bus timing characteristics analyzer indicating the results of the comparison. The visual indication displays, to the user, whether the operational signal timing parameters for the electrical signal satisfy the timing criteria. The bus timing characteristics analyzer also presents displays on a user interface of the test and measurement instrument that enable a user to navigate through results of the comparisons for each of the signal timing parameters. This navigation enables a user to more closely examine specific occurrences of detected errors in the timing characteristics of the electrical signals as part of testing the DUT.

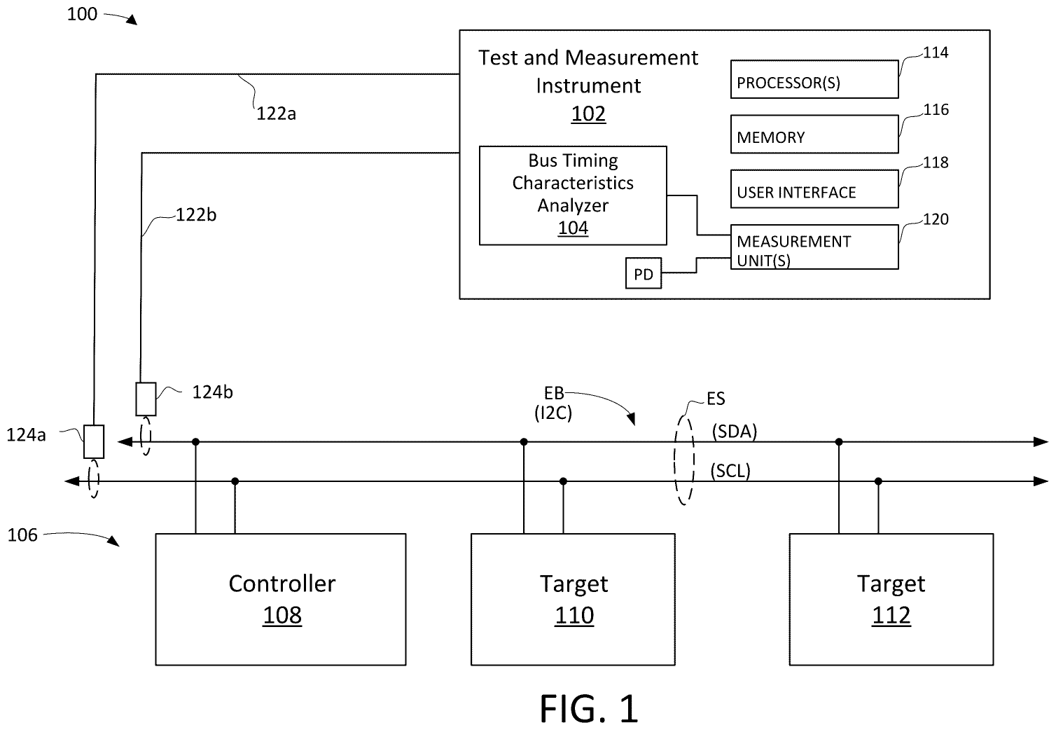

FIG. 1 illustrates a test and measurement system 100 including a test and measurement instrument 102 including a bus timing characteristics analyzer 104 that determines whether the timing characteristics of electrical signals ES being communicated over an electrical bus EB satisfy required timing criteria or characteristics for these electrical signals as defined by a bus protocol of the electrical bus. The electrical signals ES are communicated over the electrical bus EB by one or more devices 106 coupled to the electrical bus, where one of these devices is a device under test (DUT). The test and measurement instrument 102 captures or acquires the electrical signals ES being communicated by the DUT over the electrical bus for a period of time to generate an “acquisition” or “acquired waveform” for the electrical signals. The bus timing characteristics analyzer 104 analyzes the acquired waveforms to determines whether the electrical signals ES being communicated over the electrical bus EB satisfy the required timing characteristics for these electrical signals as defined by the bus protocol of the electrical bus. In the example embodiment of FIG. 1, the electrical bus EB is an inter-integrated circuit (I2C) bus with three devices 106 coupled to the I2C bus in the form of a bus controller 108 and two bus target devices or targets 110, 112. For example, the bus controller 108 may be a microcontroller and the bus targets 110 and 112 an electrically erasable programmable read-only memory (EEPROM) and a real-time clock module, respectively.

The instrument 102 includes one or more processors 114 that may be configured to execute instructions from a memory 116 and may perform any methods and/or associated steps corresponding to such instructions. A user interface 118 is coupled to the one or more processors 114 and may include, for example, a keyboard, mouse, touchscreen, output display, file storage, and/or any other controls employable by a user to interact with the instrument 102. In some embodiments, the user interface 118 may be connected to or controlled by a remote interface (not illustrated) so that a user may control operation of the instrument 102 in a remote location physically away from the instrument. A display portion of the user interface 118 may be a digital screen such as an LCD, LED, or any other monitor to display waveforms, measurements, and other data to a user. In some embodiments, a main output display of the user interface 118 may also be located remote from the instrument 102.

The instrument 102 further includes one or more measurement units 120 that perform the functions of measuring parameters and other qualities of the signals from the DUT being measured or tested by the instrument 102. Typical measurements include measuring voltage, current, and power of signals in the time domain, as well as measuring features of the signals in the frequency domain. The measurement units 120 represent any measurements that are typically performed on test and measurement instruments, and the bus timing characteristics analyzer 104 may be integrated within or coupled to such measurement units 120. The test and measurement instrument 102 is coupled through cables 122a, 122b and probes 124a, 124b to sense or detect the electrical signals ES being communicated over the I2C bus. This coupling to the electrical signals ES is represented through a dashed line for each of the probes 124a, 124b.

When the electrical bus EB is an I2C bus as in the example embodiment of FIG. 1, the electrical signals ES correspond to a serial data signal SDA and a serial clock signal SCL. Embodiments of the disclosure are directed to an I2C bus by way of example, and embodiments of the disclosure are not limited to testing devices coupled to an I2C bus. The electrical bus EB may be any of a wide variety of different types of electrical buses. The electrical bus EB may be any electrical bus where characteristics of electrical signals according to a bus protocol are clearly defined in a bus specification. In some embodiments of the disclosure, the electrical bus EB is one of the I2C bus, an I3C or “SenseWire” bus, an RS-232 bus, a Universal Serial Bus (USB) bus, an embedded USB (cUSB) bus, a Serial Peripheral Interface (SPI) bus, an embedded SPI (cSPI) bus, and a SENT (i.e., SAE J2716) bus.

In operation of the bus timing characteristics analyzer 104, a user initially provides inputs through the user interface 118 of the instrument 102 to configure the bus timing characteristics analyzer for testing of the DUT. The DUT corresponds to one of the devices 106 that is being tested, and thus is one of the bus controller 108, bus target 110, or bus target 112 in the example embodiment of FIG. 1. These user inputs include identification of the type of electrical bus EB being utilized by the DUT. In the response to the user inputs, the bus timing characteristics analyzer 104 is configured for analysis of particular timing characteristics of the electrical signals ES being communicated over the identified electrical bus EB. The electrical bus EB is the I2C bus in the example embodiment of FIG. 1. Thus, in this example, the user inputs identify the I2C bus and the bus timing characteristics analyzer 104 retrieves, from the memory 116, corresponding nominal signal timing parameters for the I2C bus that define the signal timing characteristics for the bus. These nominal signal timing parameters may alternatively be stored in another memory (not shown), such as a memory of the bus timing characteristics analyzer 104 or a memory external to the instrument 102.

In some embodiments, the nominal signal timing parameters for the I2C bus include a rise time parameter tRise for rising edges of the SDA, SCL signals, a fall time parameter tFall for falling edges of the SDA, SCL signals, and a clock period tFreq defining a clock frequency fsci, of the SCL signal. Each of the nominal signal timing parameters tRise, tFall, tFreq has a range of acceptable values, where the range is defined by corresponding minimum and maximum values for the signal timing parameter in order for the SDA, SCL signals to comply with the specifications of the bus protocol of the I2C bus. Accordingly, in some embodiments the nominal signal timing parameters for the I2C bus include a maximum rise time tRisemax and a minimum rise time tRisemin for rising edges of the SDA, SCL signals, a maximum fall time tFallmax and minimum fall time tFallmin for falling edges of the SDA, SCL signals, and a maximum clock period tFreqmax and minimum clock period tFreqmin for the SCL signal.

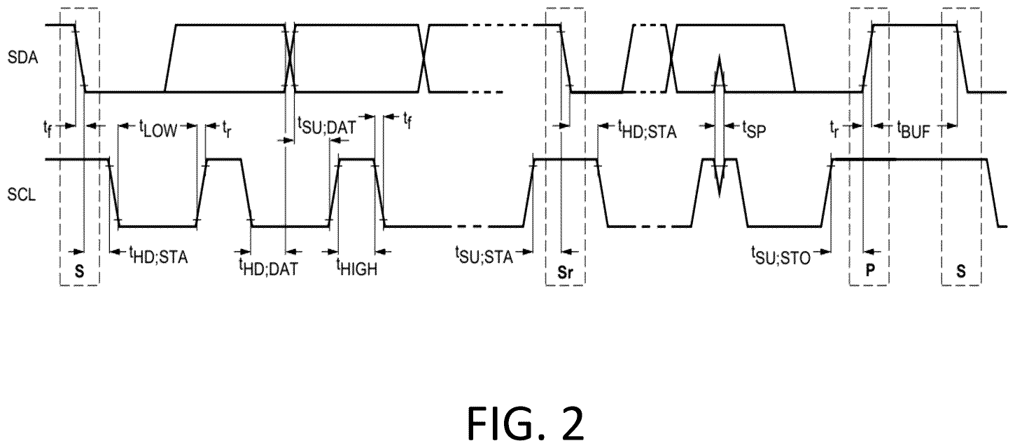

In addition to these nominal signal timing parameters, additional or alternative nominal signal timing parameters may be utilized by the bus timing characteristics analyzer 104 in some embodiments of the disclosure. For example, additional nominal signal timing parameters that may be used by the bus timing characteristics analyzer 104 include setup and hold times for the SDA signal along with setup and hold times for start and stop conditions as defined in the specifications of the bus protocol for the I2C bus. FIG. 2 is a signal timing diagram illustrating a number of nominal signal timing parameters associated with the SDA, SCL signals. In the example signal timing diagram of FIG. 2, the I2C the nominal signal timing parameters tRise and tFall are designated as tᵣ and t_{f}, and the clock period tFreq is not expressly illustrated. FIG. 2 also illustrates additional nominal signal timing parameters, which may be used by the bus timing characteristics analyzer 104 in further embodiments of the disclosure. These additional signal timing parameters include a hold start condition time tHD; STA, a minimum low clock period tLOW, a minimum high clock period tHIGH, a data hold time tHD; DAT, a setup start condition time tSU;DAT, a setup start condition time tSU;STA, a hold start condition time tHD;STA, a setup stop condition time tSU;STO, and a bus free time tBUF. Each of these additional signal timing parameters is defined in the bus protocol for the I2C bus and will be understood by those skilled in art and thus will not be described in more detail herein.

Before describing in more detail the operation of the bus timing characteristics analyzer 104, the operation of a protocol decoder PD of the instrument 102 will first be briefly described. Typically, a user would use the bus timing characteristics analyzer 104 in combination with the protocol decoder PD of the instrument 102. The protocol decoder PD is shown (FIG. 1) coupled to the measurement units 120 to receive acquisitions of the SDA, SCL signals from the measurement units 120. The protocol decoder PD then translates or decodes the bit sequences in the acquisitions of the SDA, SCL signals being communicated over the I2C bus into frames as defined by the bus protocol of the I2C bus. A designer uses the protocol decoder to verify design and operation of the DUT being tested by examining the decoded frames being communicated over the I2C bus to and from the DUT.

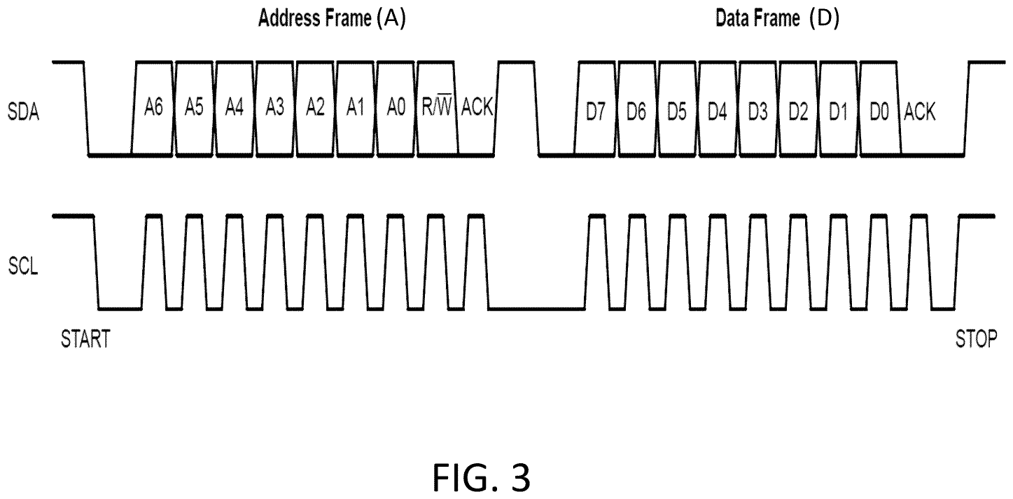

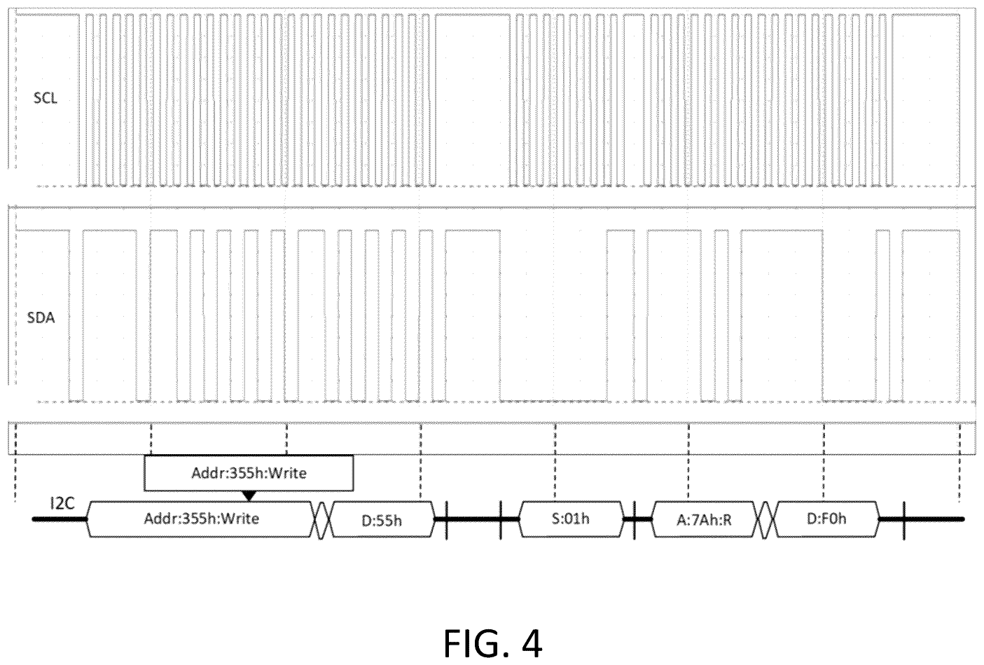

FIG. 3 is a signal timing diagram illustrating the SDA and SCL signals and showing an address frame and a data frame communicated on the I2C bus according to the bus protocol. The protocol decoder PD decodes the sequences of bits being communicated by the SDA signal using the SCL signal to generate corresponding decoded data. FIG. 4 is a signal timing diagram generated by the protocol decoder PD showing the SCL and SDA signals acquired by the instrument 102 at the top of the figure and showing, at the bottom of the figure, decoded data for bit sequences of the SDA signal, as generated by the protocol decoder. The correct values for the address frames A and data frames D being communicated are known during testing of the DUT, enabling the protocol decoder PD to detect errors in the decoded values for the address and data frames. The protocol decoder may flag or indicate detected errors in the decoded data as displayed for review by the user.

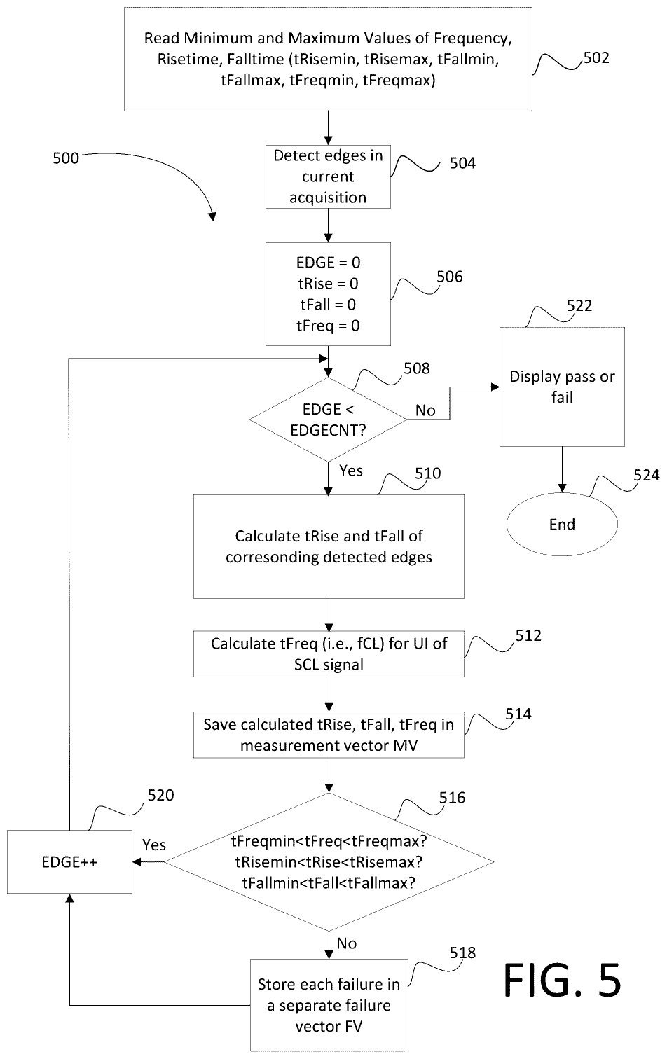

The protocol decoder PD performs no analysis of timing characteristics of the SDA, SCL signals being communicated over the I2C bus. Thus, where errors in the decoded data are caused by timing characteristics of the SDA, SCL signals not satisfying specifications given by the nominal signal timing parameters of the I2C bus, the protocol decoder PD is not able to identify such errors. The bus timing characteristics analyzer 104 according to embodiments of the disclosure enables identification of these types of errors resulting from errors in the timing characteristics of the SDA, SCL signals. The overall operation of the bus timing characteristics analyzer 104 will now be described in more detail with reference to the flowchart of FIG. 5.

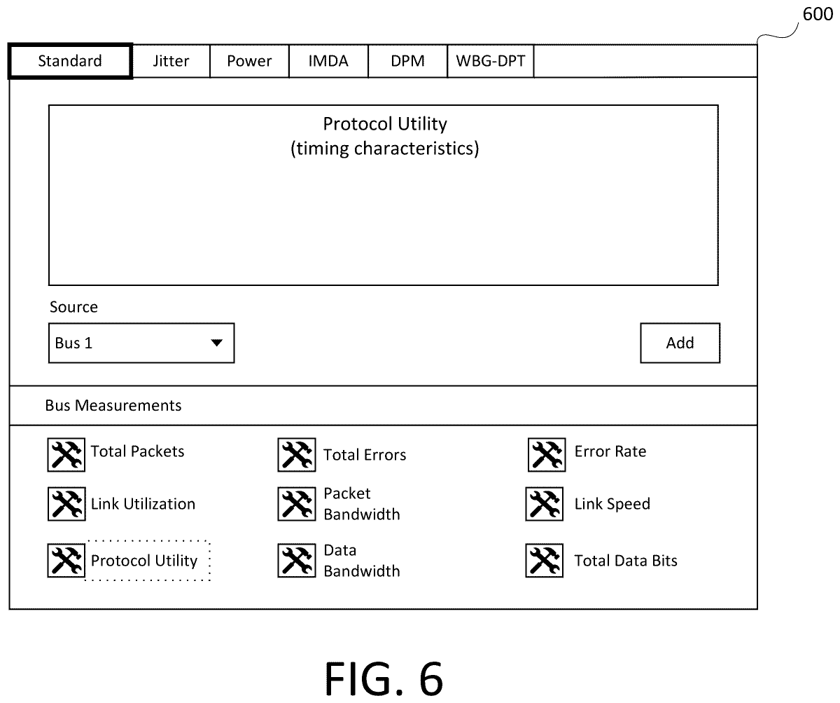

FIG. 5 is a flowchart of a process 500 executed by the bus timing characteristics analyzer 104 for analyzing the timing characteristics of the SDA, SDL signals in accordance with embodiments of the disclosure. Prior to the bus timing characteristics analyzer 104 beginning to execute the process 500, a user supplies inputs through the user interface 118 (FIG. 1) of the instrument 102 to select a “Protocol Utility” option in a configuration menu presented by the user interface. Upon selection of the Protocol Utility, the user supplies inputs to identify the type of electrical bus EB being used and the bus timing characteristics analyzer 104 thereafter performs analysis of the timing characteristics of the electrical signals ES being communicated on the electrical bus EB. Configuration of the bus timing characteristics analyzer 104 will be described in more detail below with reference to FIGS. 6-8.

Once the user provides inputs to select the I2C bus, the bus timing characteristics analyzer 104 begins execution of the process 500 at operation 502 and loads or retrieves nominal signal timing parameters for the I2C bus (i.e., the selected bus). As discussed above, in some embodiments the nominal signal timing parameters include a rise time tRise for rising edges of the SDA, SCL signals, a fall time tFall for falling edges of the SDA, SCL signals, and a clock frequency f_{CL} or clock period tFreq for the SCL signal. The nominal signal timing parameters may be specified in terms of a maximum and minimum around a nominal value, and thus may include, in some embodiments, a maximum rise time tRisemax, minimum rise time tRiscmin, a maximum fall time tFallmax, a minimum fall time tFallmin, a maximum clock period tFreqmax, and a minimum clock period tFreqmin for the SCL signal.

After retrieving the tRisemax, tRisemin, tFallmax, tFallmin, tFreqmax, and tFreqmin parameters at operation 502, the process 500 goes to operation 504 and rising and falling edges in the current acquisition or acquired waveform of the SDA, SCL signals acquired by the instrument 102 are detected. The bus timing characteristics analyzer 104 may detect these edges, or the edge detection may be performed by other components in the instrument 102, such as the measurement units 120. Whether performed by the bus timing characteristics analyzer 104 or other component in the instrument 102, once rising and falling edges in the current acquisition or acquired waveform have been detected at operation 504, the process 500 goes to operation 506 and initializes a number of operational variables that are used in calculating operational signal timing parameters for the current acquisition of the SDA, SCL signals. The operational variables include a current edge index EDGE, a total edge count EDGECNT, a rise time tRise, fall time tFall, and frequency tFreq associated with detected rising and falling edges in the current acquisition and the frequency of the SCL signal for each unit interval (UI) of the SCL signal. Each of the EDGE, tRise, tFall, and tFreq is initialized to zero and the total edge count EDGECNT is set to a total number of detected edges in the acquisition at operation 506.

From operation 506 the process 500 goes to operation 508 and determines whether a current detected edge in the acquisition as defined by the value of the edge index EDGE is less than the total edge count EDGECNT. When the determination at operation 508 is true, the process 500 goes to operation 510 and measures or calculates the rise time tRise of the detected rising edge corresponding to the current value of the edge index EDGE. In operation 510, the process 500 also measures or calculates the fall time tFall of the detected falling edge corresponding to the current value of the edge index EDGE. From operation 510, the process 500 goes to operation 512 and calculates or measures the clock period tFreq or clock frequency f_{CL} for a current unit interval UI of the SCL signal. The process 500 then goes from operation 512 to operation 514 and calculates and saves values for the rise time tRise, fall time tFall, and frequency tFreq associated with the current value of the edge index EDGE in a measurement vector MV for the current acquisition.

The process 500 then goes from operation 514 to operation 516 and determines whether each of the rise time tRise, fall time tFall, and frequency tFreq associated with the current value of the edge index EDGE satisfies the timing characteristics or timing criteria defined by the corresponding nominal signal timing parameter retrieved in operation 502. Thus, in operation 516 the process 500 determines whether the current measured or calculated rise time tRise is greater than the minimum rise time tRisemin and less than the maximum rise time tRisemax as required by the I2C bus protocol for rising edges of the SDA, SCL signals. Similarly, at operation 516 the process 500 determines in operation 516 the process 500 determines whether the current measured or calculated fall time tFall is greater than the minimum fall time tFallmin and less than the maximum fall time tFallmax as required by the I2C bus protocol for falling edges of the SDA, SCL signals. Finally, in operation 516 the process 500 also determines whether the current measured or calculated clock period tFR is greater than the minimum clock frequency tFreqmin and less than the maximum clock frequency tFreqmax as required by the I2C bus protocol for the SCL signal.

When one or more of the determinations in operation 516 is negative, the process 500 goes to operation 518 and generates a separate failure vector FV for each detected failure in operation 516. Thus, the process 500 at operation 518 generates a rising edge failure vector FV-R indicating whether the rise time tRise for the current rising edge corresponding to the current value of the edge index EDGE satisfies the timing criteria defined by the corresponding nominal timing parameters (i.e., whether tRisemin<tRise<tRisemax). A pass or fail value is stored in the rising edge failure vector FV-R in operation 518 to indicate whether the rise time tRise for the current rising edge has passed or failed the timing criteria. The process 500 at operation 518 also generates a falling edge failure vector FV-F and a clock frequency failure vector FV-CF in operation 518. At operation 518 a pass or fail value is stored in each of the falling edge failure vector FV-F and clock frequency failure vector FV-CF to indicate whether the fall time tFall and clock frequency fsCL for the falling edge and clock period tFreq corresponding to the value of the current edge index EDGE has passed or failed the corresponding timing criteria.

From operation 518 the process 500 goes to operation 520 and the value of the current edge index EDGE is incremented, and the process then goes back to operation 508 and determines whether the current value of the edge index EDGE is less than the total edge count EDGECNT. In addition, the process 500 also goes directly to the operation 520 when all the determinations in operation 516 are positive, meaning no failure has been detected for any of the signal timing parameters tRise, tFall, tFreq being analyzed. Each of the rising edge failure vector FV-R, falling edge failure vector FV-F, clock frequency failure vector FV-CF initially stores a pass value for the tRise, tFall, and tFreq corresponding to the current edge index EDGE. Thus, when all the determinations in operation 516 are positive, the process 500 goes immediately to operation 520 and the current edge index EDGE is incremented, with all the initial values for the tRise, tFall, and tFreq that correspond the current edge index EDGE remain at the initially set pass values in each of the FV-R, FV-F, FV-CF vectors.

The process 500 continues executing the operations 508-520 until the determination in operation 508 is negative, indicating the timing characteristics of all detected edges in the current acquisition have been measured and determined to have passed or failed the corresponding timing criteria. When the determination in operation 508 is negative, the process 500 goes to operation 522 and displays, through the user interface 118 (FIG. 1), whether each of the measured operational signal timing parameters tRise, tFall, tFreq has passed or failed the timing criteria for the I2C bus as defined by the corresponding nominal signal timing parameters tRisemin, tRisemax, tFallmin, tFallmax, tFreqmin, and tFreqmax.

The measured operational signal timing parameters tRise, tFall, tFreq are determined to have failed the associated timing criteria when at least one rising or falling edge, or the clock frequency for at least one unit interval UI, does not satisfy the timing criteria as defined by the corresponding nominal signal timing parameters. At operation 522, the process 500 displays a “pass” indication for a measured signal timing parameter tRise, tFall, tFreq when all edges or the frequency or all unit intervals UI for the SDA, SCL signals satisfy the associated timing criteria. Conversely, when a failure is detected, the process 500 at operation 522 displays a “fail” indication for the measured signal timing parameter tRise, tFall, tFreq. In addition, when a failure is detected for a measured signal timing parameter tRise, tFall, tFreq, the process 500 at operation 522 utilizes the associated failure vector FV-R, FV-F, FV-CF to enable a user to navigate through the failure vector and examine each instance of a failure for the corresponding signal SDA, SCL. The operation of the bus timing characteristics analyzer 104 in executing the operation 522 to present pass and fail indications and allow the user to navigate through and more closely examine failures will be described in more detail below with reference to FIGS. 6-8. After operation 522, the process 500 goes to operation 524 and ends.

FIG. 6 illustrates a sample configuration display 600 rendered on the user interface 118 by the bus timing characteristics analyzer 104 to enable configuration by a user of the bus timing characteristics analyzer 104 in accordance with embodiments of the disclosure. In the configuration display 600, a “Protocol Utility” option is added to an existing configuration menu and the user selects this option to configure the bus timing characteristics analyzer 104 to perform analysis of timing characteristics of electrical signals generated by a DUT. The existing configuration menu presented in the configuration display 600 provides several signal analysis options the instrument 102 may perform on acquired waveforms. These analysis options are selected through additional tabs at the top of the configuration display 600 and include a WBG-DPT tab for selecting wide bandgap double pulse testing of a DUT, a DPM tab for selecting digital power management testing of a DUT, an IMDA tab for selecting inverter motor drive analysis testing of a DUT, a Power tab for selecting power testing of a DUT, and a Jitter tab for selecting jitter analysis of a DUT.

The user selects the Protocol Utility through a Standard tab, which is presented in the upper left corner of the configuration display 600. The Standard tab is selected by the user and thereafter the user selects the Protocol Utility option, which is presented in the lower left portion of the configuration display 600 as one of a number of different types of bus measurements that the instrument 102 may perform on electrical signals of a DUT. The Standard tab is shown through a thicker line and Protocol tab through a dashed line in FIG. 6 to indicate these two tabs have been selected by a user. The then user selects, through a Source field displayed in the middle left portion the configuration display 600, a bus source to define the type of bus being analyzed, such as an I2C bus. The Source field is shown as Bus 1 in FIG. 6.

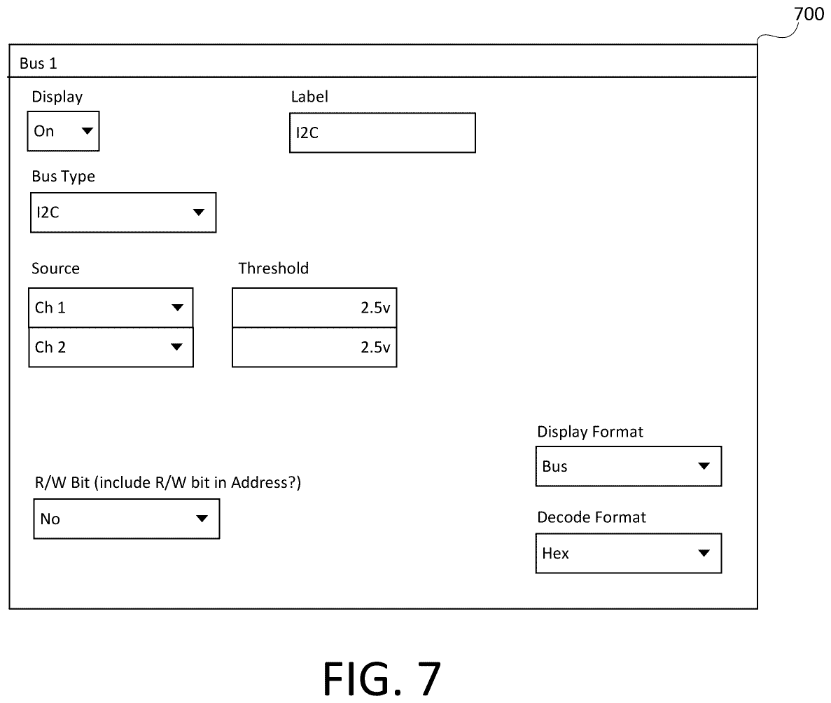

Upon selecting the Source field, a user may then configure parameters for the selected type of bus that is the source of the electrical signals being analyzed. Selection of the Source field causes display of a bus configuration display 700 as shown in FIG. 7 that is displayed by the user interface 118 of the instrument 102. The configuration display 700 includes a Display field to allow a user to display, or not display, the output of the bus timing characteristics analyzer 104 on the user interface 118. A Label field allows the user to assign a desired label to the bus being analyzed. The type of bus being analyzed is set in a Bus Type field, and is shown as being the I2C bus in the example of FIG. 7. As discussed above, different types of buses may be analyzed and the user selects the appropriate bus through the Bus Type field.

The user then selects the appropriate channels CH on the instrument for the corresponding electrical signals of the selected type of bus. The I2C bus includes the SDA and SCL signals as described above. In the example of FIG. 6, one of the SDA, SCL signals is coupled to a first channel CH1 of the instrument 104 and the other of the SDA, SCL signals is coupled to a second channel CH2 of the instrument. A Threshold field in the display 700 is used to set a respective threshold voltage for the SDA, SCL signals coupled to the first and second channels CH1, CH2 of the instrument 102. A R/W Bit field in the display 700 provides the user with an option to include a read/write bit R/W in the decoded addresses on the I2C bus. A Display Format field allow the user to select the desired format for display of the SDA, SCL signals, namely whether the signals are displayed as decoded frames on the bus (i.e., “Bus” as shown in FIG. 7) or as time varying voltage levels for these signals. When the Bus format is selected, each value for each the decoded frames is displayed, as shown for the I2C bus at the bottom of FIG. 4. A Display Format field allows a user to select the desired format for the values of the decoded frames to be displayed, such as hexadecimal (Hex), binary, decimal, and other format options as well may also be provided.

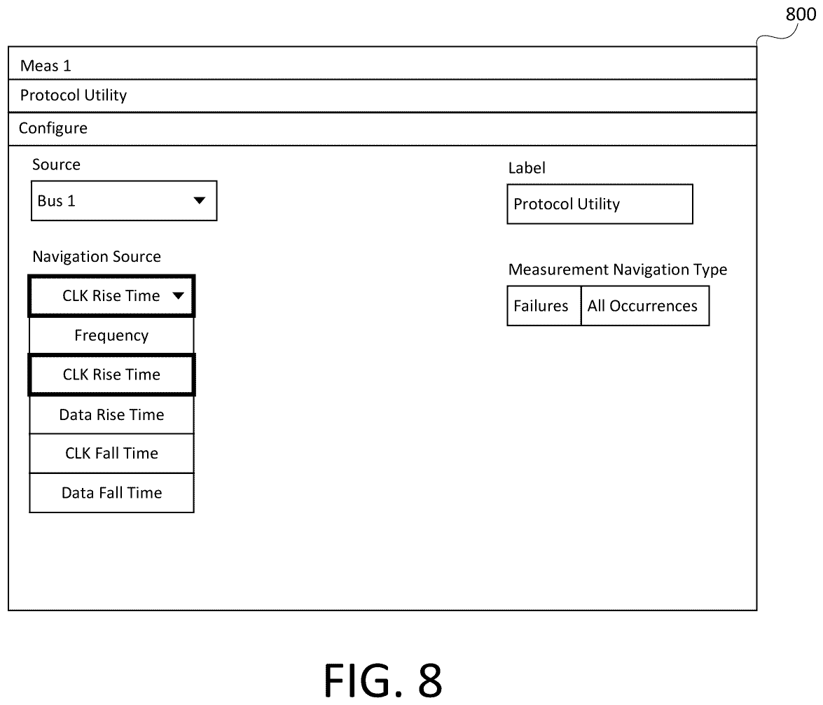

FIG. 8 illustrates a bus timing results configuration display 800 allowing the user to configure the desired results of the analysis of the bus timing characteristics analyzer 104 that are to be displayed for review by the user. More specifically, the configuration display 800 includes a Navigation Source field in the lower left portion of the display, which allows the user to select the desired timing characteristic or criteria to be displayed for review by the user. The Source field is Bus 1 in the example of FIG. 8 where Bus 1 corresponds to the I2C bus. The Navigation Source field accordingly provides the user with options to select a desired one of the timing parameters that are analyzed by the bus timing characteristics analyzer 104.

As discussed above, in embodiments these timing parameters include a frequency of the clock signal SCL, a rise time for rising edges of the SCL signal, a fall time for falling edges of the SCL signal, and rise and fall times for rising and falling edges of the data signal SDA. These different timing parameters are shown in drop down sub-fields available for the Navigation Source field in the configuration display 800 of FIG. 8. The rising edges of the SCL signal is selected as shown through a thicker line for this sub-field. A Measurement Navigation Type field is also part of the configuration display 800 and allows a user to determine whether to review all occurrences of the selected timing parameter or only occurrences where failures occurred. This selection is made through an All Occurrences sub-field and a Failure sub-field of the Measurement Navigation Type field. For example, where the rise time of rising edges of the SCL signal is selected as in the example of FIG. 8, selecting the All Occurrences sub-field as in the example of FIG. 8 will allow a user to navigate through and review the rise time parameter calculated for all rising edges of the SCL signal in the current acquisition being analyzed by the bus timing characteristics analyzer 104.

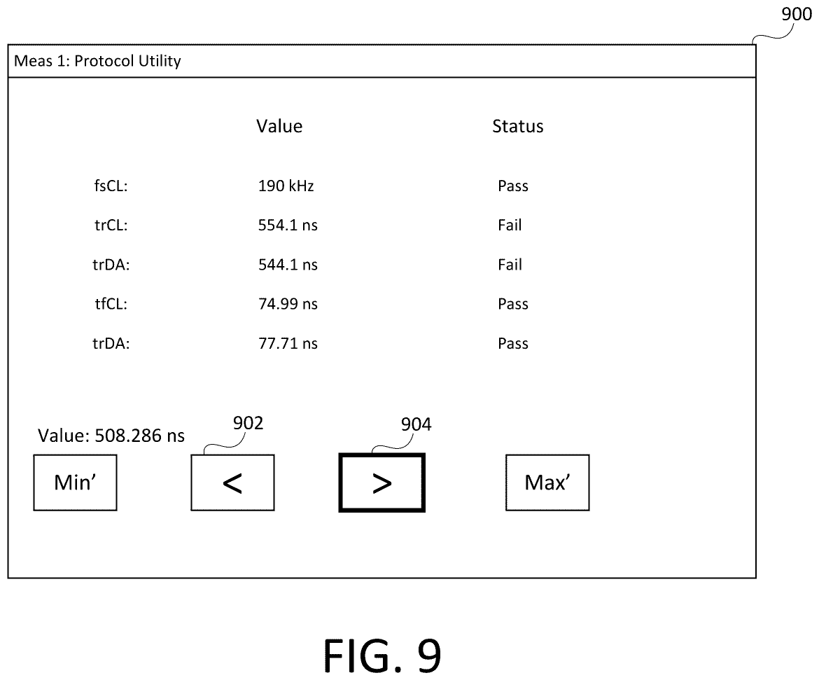

FIG. 9 illustrates a bus timing results display 900 through the user interface 118 of the instrument 104 by the bus timing characteristics analyzer 104 to allow the user to review the results of the timing characteristics analysis for the timing parameters being analyzed. In the example of FIG. 9, the bus timing results configuration display 800 shows, for the I2C bus, the measured or operational timing parameters previously discussed, namely the rise and fall time parameters for the rising and falling edges of the SDA, SCL signals along with the frequency of the SCL signal. These operational signal timing parameters are designated as follows in the configuration display 900: the rise time for rising edges of the SCL signal is designated as a clock rise time trCL; the fall time for falling edges of the SCL signal is designated as a clock fall time tfCL; the rise time for rising edges of the SDA signal is designated as a data rise time trDA; the fall time for falling edges of the SDA signal is designated as a data fall time tfDA; and the frequency of the SCL signal is designated as a clock frequency fsCL.

The bus timing results display 900 also includes a Value field for each of the trCL, tfCL, trDA, tfDA, and fsCL timing parameters showing the value for the timing parameter. A Status field for each timing parameter shows whether the timing parameter has passed or failed the analysis by the bus timing characteristics analyzer 104. A user may then use navigation buttons 902, 904 to navigate through a selected signal timing parameter to review instances of a desired one of the parameters. User navigation button 904 is shown as being selected in FIG. 9 through a thicker line for this button. In some embodiments, where there are no violations for a given signal timing parameter, navigation is disabled for that parameter. For example, in example of FIG. 9 no navigation through instances of the trDA, tfCL, and fsCL parameters is provided since these parameters passed the analysis as indicated by the corresponding Status fields. Each of the trCL and trDA parameters may then be navigated through using the buttons 902, 904 as these parameters have failed the analysis as indicated by the corresponding status fields. Minimum and maximum buttons Min′, Max′ in the bus timing results display 900 enable a user to identify minimum and maximum values for a selected timing parameter.

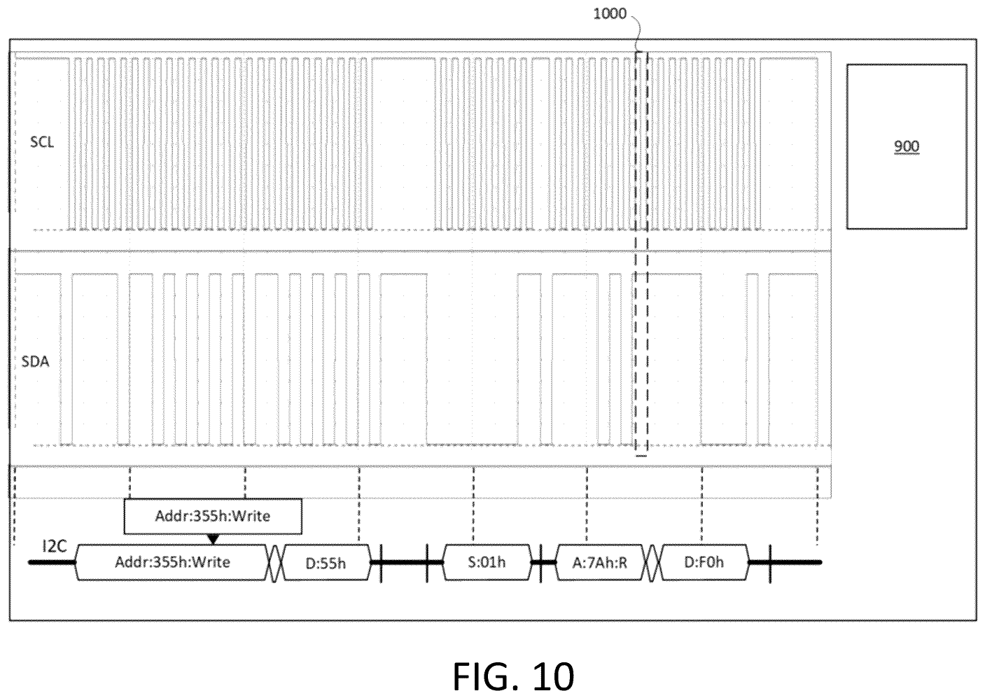

In embodiments, the bus timing characteristics analyzer 104 performs additional analysis of each of the signal timing parameters being analyzed. For example, in embodiments the bus timing characteristics analyzer 104 calculates a mean value, a minimum value, a maximum value and a standard deviation for each of the signal timing parameters tfCL, trCL, tfCL, trDA, and tfDA. Moreover, in embodiments the navigation through a selected signal timing parameter using the buttons 902, 904 may also be illustrated by the user interface 118 in a time domain representation of the corresponding signal SDA, SCL to enable the user to see instances of the signal timing parameter being analyzed in the time domain representation of the corresponding SDA, SCL signal. FIG. 10 illustrates another example bus timing results display 1000 including the bus timing results display 900 of FIG. 9 in the upper right corner along with time domain representations of the SDA, SCL signals and decoded frames shown in the left portion of the frame. In this embodiment, a particular instance of a failure of the timing parameter being displayed in bus timing results display 900 is also identified or tagged through a dashed box 1000 in the time domain representations of the SDA, SCL signals.

In some embodiments, the nominal signal timing parameters for the I2C bus include parameters for a standard mode and a fast mode of operation. For the standard mode, the nominal signal timing parameters may include a rise time parameter tRise of 1000 nanoseconds (ns) for rising edges of the SDA and SCL signals, a fall time parameter tFall of 300 ns for falling edges of the SDA, SCL signals, a clock frequency tFreq of less than or equal to 100 KHz, and a minimum low clock period tLOW of 4.7 microseconds (μs) and minimum high clock period tHIGH of 4.0 μs. For the fast mode, the nominal signal timing parameters may include a rise time parameter tRise of 20 ns to 300 ns for rising edges of the SDA and SCL signals, a fall time parameter tFall of 20 ns to 300 ns for falling edges of the SDA, SCL signals, a clock frequency tFreq of less than or equal to 400 KHz, and a minimum low clock period tLOW of 1.3 us and minimum high clock period tHIGH of 0.6 μs.

Aspects of the disclosure may operate on a particularly created hardware, on firmware, digital signal processors, or on a specially programmed general purpose computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

### EXAMPLES

Illustrative examples of the technologies disclosed herein are provided below. A configuration of the technologies may include any one or more, and any combination of, the examples described below.

Example 1 is a test and measurement instrument including one or more processors configured to control acquisition of a plurality of electrical signals being communicated over an electrical bus according to a bus protocol by a device under test; and a bus timing characteristics analyzer configured to identify nominal signal timing parameters for the acquired plurality of electrical signals, the nominal signal timing parameters being defined by the bus protocol and defining timing criteria for the plurality of electrical signals; measure operational signal timing parameters for each of the acquired plurality of electrical signals; compare, for each of the acquired plurality of electrical signals, the operational signal timing parameters to the nominal signal timing parameters to determine whether the operational signal timing parameters satisfy the timing criteria; and display, on the test and measurement instrument, a visual indication for each of the plurality of electrical signals indicating whether the operational signal timing parameters for the electrical signal satisfy the timing criteria.

Example 2 is the test and measurement instrument of Example 1, where the bus timing characteristics analyzer is further configured, in order to measure the operational signal timing parameters for each of the acquired plurality of electrical signals, to detect edges in each of the acquired plurality of electrical signals; determine whether each edge is a rising edge or a falling edge; and measure the operational signal timing parameters for each of the acquired plurality of electrical signals using the rising and falling edges of the electrical signal.

Example 3 is the test and measurement instrument of Example 1 or Example 2, where the acquired plurality of electrical signals include at least one data signal and where the operational signal timing parameters for the at least one data signal include a rise time measured for each rising edge and a fall time measured for each falling edge of the at least one data signal.

Example 4 is the test and measurement instrument of any one of Examples 1-3, where the nominal signal timing parameters include a nominal rise time signal timing parameter and a nominal fall time signal timing parameter, and where the bus timing characteristics analyzer is further configured to compare, for the at least one data signal, the measured rise time for each rising edge to the nominal rise time signal timing parameter; and compare, for the at least one data signal, the measured fall time for each falling edge to the nominal fall time signal timing parameter.

Example 5 is the test and measurement instrument of any one of Examples 1-4, where the nominal rise time signal timing parameter includes a range around a nominal value, the range being defined by a minimum and a maximum permissible value for the nominal rise time signal timing parameter, and where the nominal fall time signal timing parameter includes a range around a nominal value, the range being defined by a minimum and a maximum permissible value for the nominal fall time signal timing parameter, and where the bus timing characteristics analyzer is further configured to determine whether the measured rise time for each rising edge of the at least one data signal has a value within the range of the nominal rise time signal timing parameter; and determine whether the measured fall time for each falling edge of the at least one data signal has a value within the range of the nominal fall time signal timing parameter.

Example 6 is the test and measurement instrument of any one of Examples 1-5, where the nominal signal timing parameters further include a setup time tSU and a hold time tHD for the at least one data signal.

Example 7 is the test and measurement instrument of any one of Examples 1-6, where the acquired plurality of electrical signals further includes a clock signal and where the nominal signal timing parameters for the clock signal include a nominal clock frequency, a nominal rise time signal timing parameter, and a nominal fall time signal timing parameter.

Example 8 is the test and measurement instrument of any one of Examples 1-7, where the visual indication for each of the plurality of electrical signals indicates a pass condition when all operational signal timing parameters satisfy the timing criteria for the electrical signal and indicates a fail condition when one or more of the operational signal timing parameters do not satisfy the timing criteria.

Example 9 is the test and measurement instrument of any one of Examples 1-8, where the electrical bus is one of an inter-integrated circuit (I2C) bus, an I3C or SenseWire bus, RS-232 bus, a Universal Serial Bus (USB) bus, an embedded USB (cUSB) bus, a Serial Peripheral Interface (SPI) bus, an embedded SPI (eSPI), and a SENT bus.

Example 10 is the test and measurement instrument of any one of Examples 1-9, where the test and measurement instrument may include an oscilloscope.

Example 11 is a test and measurement system including a number of electronic devices; an electrical bus interconnecting the electronic devices, one of the electronic devices being a device under test (DUT) and the electrical bus communicating electrical signals over having nominal signal timing parameters being defined by a bus protocol of the electrical bus, the nominal signal timing parameters defining timing criteria for the electrical signals; and a test and measurement instrument, including one or more processors configured to control acquisition of the electrical signals; and a bus timing characteristics analyzer configured to: identify nominal signal timing parameters for the acquired electrical signals, the nominal signal timing parameters being defined by the bus protocol and defining timing criteria for the electrical signals; measure operational signal timing parameters for each of the acquired electrical signals; compare, for each of the acquired electrical signals, the operational signal timing parameters to the nominal signal timing parameters to determine whether the operational signal timing parameters satisfy the timing criteria; and display, on the test and measurement instrument, a visual indication for each of the electrical signals indicating whether the operational signal timing parameters for the electrical signal satisfy the timing criteria.

Example 12 is the test and measurement system of Example 11, where the electrical bus is one of an inter-integrated circuit (I2C) bus, an I3C or SenseWire bus, RS-232 bus, a Universal Serial Bus (USB) bus, an embedded USB (eUSB) bus, a Serial Peripheral Interface (SPI) bus, an embedded SPI (eSPI), and a SENT bus.

Example 13 is the test and measurement system of Example 11 or Example 12, where the test and measurement instrument further may include a memory, and where the nominal signal timing parameters are stored in the memory.

Example 14 is the test and measurement system of any one of Examples 11-13, where the test and measurement instrument may include an oscilloscope.

Example 15 is the test and measurement system of any one of Examples 11-14, where the acquired electrical signals include a clock signal and a data signal, where the nominal signal timing parameters include rise time and fall time signal timing parameters for rising and falling edges of the clock and data signals, and further include a frequency signal timing parameter for the clock signal.

Example 16 is the test and measurement system of any one of Examples 11-15, where the test and measurement instrument further may include a protocol decoder configured to translate bit sequences in the acquisitions of electricals signals into frames in accordance with the bus protocol of the electrical bus.

Example 17 is a method of measuring operational signal timing parameters of electrical signals being communicated over an electrical bus, the method including retrieving, by a test and measurement instrument, nominal signal timing parameters for the electrical signals, the nominal signal timing parameters being defined by a bus protocol of the electrical bus and defining timing criteria for the electrical signals; acquiring, in the test and measurement instrument, the electrical signals; detecting, in the test and measurement instrument, edges in the acquired electrical signals; measuring, in the test and measurement instrument, operational signal timing parameters associated with the detected edges of the acquired electrical signals; comparing, in the test and measurement instrument, the operational signal timing parameters to the nominal signal timing parameters to determine whether the operational signal timing parameters satisfy the timing criteria; storing, in the test and measurement instrument, the results of the comparing; and displaying, on the test and measurement instrument, a pass or fail indication for each of the electrical signals based on the stored results of the comparing.

Example 18 is the method of Example 17, where the electrical bus is an I2C bus and the electrical signals include a clock signal and a data signal.

Example 19 is the method of Example 17 or Example 18, where the nominal signal timing parameters include a rise time tRise for each rising edge clock and data signals, a fall time tFall for each falling edge of the clock and data signals, a clock frequency tFreq of the clock signal, a hold start condition time tHD;STA, a minimum low clock period tLOW, a minimum high clock period tHIGH, a data hold time tHD;DAT, a setup start condition time tSU;DAT, a setup start condition time tSU;STA, a hold start condition time tHD;STA, a setup stop condition time tSU;STO, and a bus free time tBUF.

Example 20 is the method of any one of Examples 17-19, where the nominal signal timing parameters include, for each nominal signal timing parameter, a maximum value and a minimum value.

The previously described versions of the disclosed subject matter have many advantages that were either described or would be apparent to a person of ordinary skill. Even so, these advantages or features are not required in all versions of the disclosed apparatus, systems, or methods.

Additionally, this written description makes reference to particular features. It is to be understood that the disclosure in this specification includes all possible combinations of those particular features. Where a particular feature is disclosed in the context of a particular aspect or example, that feature can also be used, to the extent possible, in the context of other aspects and examples.

Also, when reference is made in this application to a method having two or more defined steps or operations, the defined steps or operations can be carried out in any order or simultaneously, unless the context excludes those possibilities.

Although specific examples of the invention have been illustrated and described for purposes of illustration, it will be understood that various modifications may be made without departing from the spirit and scope of the invention. Accordingly, the invention should not be limited except as by the appended claims.

We claim:

1. A test and measurement instrument, comprising:
one or more processors configured to control acquisition of a plurality of electrical signals being communicated over an electrical bus according to a bus protocol by a device under test; and
a bus timing characteristics analyzer configured to:
identify nominal signal timing parameters for the acquired plurality of electrical signals, the nominal signal timing parameters being defined by the bus protocol and defining timing criteria for the plurality of electrical signals;
measure operational signal timing parameters for each of the acquired plurality of electrical signals;
compare, for each of the acquired plurality of electrical signals, the operational signal timing parameters to the nominal signal timing parameters to determine whether the operational signal timing parameters satisfy the timing criteria; and
display, on the test and measurement instrument, a visual indication for each of the plurality of electrical signals indicating whether the operational signal timing parameters for the electrical signal satisfy the timing criteria.

2. The test and measurement instrument of claim 1, wherein the bus timing characteristics analyzer is further configured, in order to measure the operational signal timing parameters for each of the acquired plurality of electrical signals, to:
detect edges in each of the acquired plurality of electrical signals;
determine whether each edge is a rising edge or a falling edge; and
measure the operational signal timing parameters for each of the acquired plurality of electrical signals using the rising and falling edges of the electrical signal.

3. The test and measurement instrument of claim 2, wherein the acquired plurality of electrical signals include at least one data signal and wherein the operational signal timing parameters for the at least one data signal include a rise time measured for each rising edge and a fall time measured for each falling edge of the at least one data signal.

4. The test and measurement instrument of claim 3, wherein the nominal signal timing parameters include a nominal rise time signal timing parameter and a nominal fall time signal timing parameter, and wherein the bus timing characteristics analyzer is further configured to:
compare, for the at least one data signal, the measured rise time for each rising edge to the nominal rise time signal timing parameter; and
compare, for the at least one data signal, the measured fall time for each falling edge to the nominal fall time signal timing parameter.

5. The test and measurement instrument of claim 4, wherein the nominal rise time signal timing parameter includes a range around a nominal value, the range being defined by a minimum and a maximum permissible value for the nominal rise time signal timing parameter, and wherein the nominal fall time signal timing parameter includes a range around a nominal value, the range being defined by a minimum and a maximum permissible value for the nominal fall time signal timing parameter, and wherein the bus timing characteristics analyzer is further configured to:
determine whether the measured rise time for each rising edge of the at least one data signal has a value within the range of the nominal rise time signal timing parameter; and
determine whether the measured fall time for each falling edge of the at least one data signal has a value within the range of the nominal fall time signal timing parameter.

6. The test and measurement instrument of claim 5, wherein the nominal signal timing parameters further include a setup time tSU and a hold time tHD for the at least one data signal.

7. The test and measurement instrument of claim 1, wherein the acquired plurality of electrical signals further includes a clock signal and wherein the nominal signal timing parameters for the clock signal include a nominal clock frequency, a nominal rise time signal timing parameter, and a nominal fall time signal timing parameter.

8. The test and measurement instrument of claim 1, wherein the visual indication for each of the plurality of electrical signals indicates a pass condition when all operational signal timing parameters satisfy the timing criteria for the electrical signal and indicates a fail condition when one or more of the operational signal timing parameters do not satisfy the timing criteria.

9. The test and measurement instrument of claim 1, wherein the electrical bus is one of an inter-integrated circuit (I2C) bus, an I3C or “SenseWire” bus, RS-232 bus, a Universal Serial Bus (USB) bus, an embedded USB (eUSB) bus, a Serial Peripheral Interface (SPI) bus, an embedded SPI (eSPI), and a SENT bus.

10. The test and measurement instrument of claim 1, wherein the test and measurement instrument comprises an oscilloscope.

11. A test and measurement system, comprising:
a number of electronic devices;
an electrical bus interconnecting the electronic devices, one of the electronic devices being a device under test (DUT) and the electrical bus communicating electrical signals over having nominal signal timing parameters being defined by a bus protocol of the electrical bus, the nominal signal timing parameters defining timing criteria for the electrical signals; and
a test and measurement instrument, including:
one or more processors configured to control acquisition of the electrical signals; and
a bus timing characteristics analyzer configured to:
identify nominal signal timing parameters for the acquired electrical signals, the nominal signal timing parameters being defined by the bus protocol and defining timing criteria for the electrical signals;
measure operational signal timing parameters for each of the acquired electrical signals;
compare, for each of the acquired electrical signals, the operational signal timing parameters to the nominal signal timing parameters to determine whether the operational signal timing parameters satisfy the timing criteria; and
display, on the test and measurement instrument, a visual indication for each of the electrical signals indicating whether the operational signal timing parameters for the electrical signal satisfy the timing criteria.

12. The test and measurement system of claim 11, wherein the electrical bus is one of an inter-integrated circuit (I2C) bus, an I3C or “SenseWire” bus, RS-232 bus, a Universal Serial Bus (USB) bus, an embedded USB (eUSB) bus, a Serial Peripheral Interface (SPI) bus, an embedded SPI (eSPI), and a SENT bus.

13. The test and measurement system of claim 11, wherein the test and measurement instrument further comprises a memory, and wherein the nominal signal timing parameters are stored in the memory.

14. The test and measurement system of claim 11, wherein the test and measurement instrument comprises an oscilloscope.

15. The test and measurement system of claim 11, wherein the acquired electrical signals include a clock signal and a data signal, wherein the nominal signal timing parameters include rise time and fall time signal timing parameters for rising and falling edges of the clock and data signals, and further include a frequency signal timing parameter for the clock signal.

16. The test and measurement system of claim 11, wherein the test and measurement instrument further comprises a protocol decoder configured to translate bit sequences in the acquisitions of electricals signals into frames in accordance with the bus protocol of the electrical bus.

17. A method of measuring operational signal timing parameters of electrical signals being communicated over an electrical bus, the method comprising:
retrieving, by a test and measurement instrument, nominal signal timing parameters for the electrical signals, the nominal signal timing parameters being defined by a bus protocol of the electrical bus and defining timing criteria for the electrical signals;
acquiring, in the test and measurement instrument, the electrical signals;
detecting, in the test and measurement instrument, edges in the acquired electrical signals;
measuring, in the test and measurement instrument, operational signal timing parameters associated with the detected edges of the acquired electrical signals;
comparing, in the test and measurement instrument, the operational signal timing parameters to the nominal signal timing parameters to determine whether the operational signal timing parameters satisfy the timing criteria;
storing, in the test and measurement instrument, the results of the comparing; and
displaying, on the test and measurement instrument, a pass or fail indication for each of the electrical signals based on the stored results of the comparing.

18. The method of claim 17, wherein the electrical bus is an I2C bus and the electrical signals include a clock signal and a data signal.

19. The method of claim 18, wherein the nominal signal timing parameters include a rise time tRise for each rising edge clock and data signals, a fall time tFall for each falling edge of the clock and data signals, a clock frequency tFreq of the clock signal, a hold start condition time tHD;STA, a minimum low clock period tLOW, a minimum high clock period tHIGH, a data hold time tHD;DAT, a setup start condition time tSU;DAT, a setup start condition time tSU;STA, a hold start condition time tHD;STA, a setup stop condition time tSU;STO, and a bus free time tBUF.

20. The method of claim 17, wherein the nominal signal timing parameters include, for each nominal signal timing parameter, a maximum value and a minimum value.
